(19) United States
(12) Patent Application Publication
(10) Pub. No.: US 2010/0263603 A1
(43) Pub. Date: Oct. 21, 2010

(54) ANIMAL GARMENT WITH INTEGRATED SOUND DEVICE

(76) Inventor: Matthew Baron, Philadelphia, PA (US)

Correspondence Address: Matthew Baron, Apartment 1911, 233 South 6th Street, Philadelphia, PA, 19106, US

(21) Appl. No.: 12/574,432

(22) Filed: Oct. 6, 2009

Related U.S. Application Data
(60) Provisional application No. 61/212,726, filed on Apr. 16, 2009.

(51) Int. Cl. A01K 29/00; H01L 31/042; H04R 1/00; G05B 19/02

(52) U.S. Cl. 119/850; 136/244; 381/182; 340/825.24

(57) ABSTRACT

In one aspect, a garment for a dog is provided. The garment for a dog may include a pair of speakers comprising a left speaker and a right speaker. The left speaker may be placed in a left side of the garment between the front and rear legs of the dog and the right speaker may be placed in a right side of the garment between the front and rear legs of the dog. An audio source may be connected to the pair of speakers. The garment may include a wireless receiver adapted to receive signals from a remote control. The garment may include a control processor adapted to control the audio source according to the received signals.

### BACKGROUND

Many people own pets such as dogs, cats, horses, etc. Pet owners typically spend many hours a day with their pets and integrate them into many aspects of their lives and family. In addition to companionship, many pets provide useful services to their owners and often the general public. For example, dogs often provide services to the handicapped, police and firefighters, and may be used to assist in rescue operations.

Many people also own or rely on a number of electronic devices. For example, people typically carry items such as a cell phone, MP3 player, internet enabled device etc. Public servants such as police, firefighters, and rescue workers may carry additional electronic such as radios and public address systems.

While many people carry electronics and own pets, often it is difficult to integrate the joys of pet ownership with the use of the electronic devices. For example, a listener of an MP3 player may be too distracted to enjoy their pet, or a police officer may fail to fully utilize their police dog because they are using a public address system.

### SUMMARY

In one aspect, a garment for a dog is provided. The garment for a dog may include a pair of speakers comprising a left speaker and a right speaker. The left speaker may be placed in a left side of the garment between the front and rear legs of the dog and the right speaker may be placed in a right side of the garment between the front and rear legs of the dog. An audio source may be connected to the pair of speakers. The garment may include a wireless receiver adapted to receive signals from a remote control. The garment may include a control processor adapted to control the audio source according to the received signals.

Implementations may include one or more of the following features. The audio source may be one of an mp3 player and a microphone. The garment may include an amplifier connected to the audio source and the pair of speakers. The garment may include a power source. The power source may be a rechargeable battery. The power source may be a solar panel attached to the garment. The garment may include a wireless router and an internet source. The internet source may be a cellular phone. The remote control may be a software application.

A garment for an animal may be provided. The garment may include a pair of speakers. The garment may include an amplifier connected to the speakers through a plurality of wires located within the garment. The garment may include an interface connected to the amplifier through the plurality of wires and adapted to connect to an external audio source.

Implementations may include one or more of the following features. The garment may include a control processor adapted to receive commands relating to the operation of the external source, and control the external source through the interface. The garment may include a wireless receiver adapted to receive commands relating to the operation of the external source from a remote control, and provide the received commands to the control processor. The interface may be a wireless interface and the external audio source may be a wireless external audio source. The wireless audio source may be a microphone. The garment may include a power supply connected to the amplifier through the plurality of wires. The power supply may be a solar panel based power supply. The garment may include at least one power outlet. The power outlet may be adapted to provide power from the power supply to a device connected to the power outlet. The power outlet may be a USB outlet. The animal may be one of a dog, a cat, a horse, or a monkey.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIGS. 1a and 1b are side and top perspective illustrations of an example garment for an animal with integrated speakers;

FIG. 2 is an illustration of the components of an example garment for an animal;

FIG. 3 is an illustration of the components of an example garment for an animal;

FIG. 4 is an illustration of the components of an example garment for an animal;

FIG. 5 is an illustration of the components of an example garment for an animal;

FIG. 6 is an illustration of the components of an example garment for an animal;

FIG. 7 is an illustration of the components of an example garment for an animal;

FIG. 8 is a block diagram of an example computing environment that may be used in conjunction with example embodiments and aspects.

### DETAILED DESCRIPTION

### I. Overview of the Garment

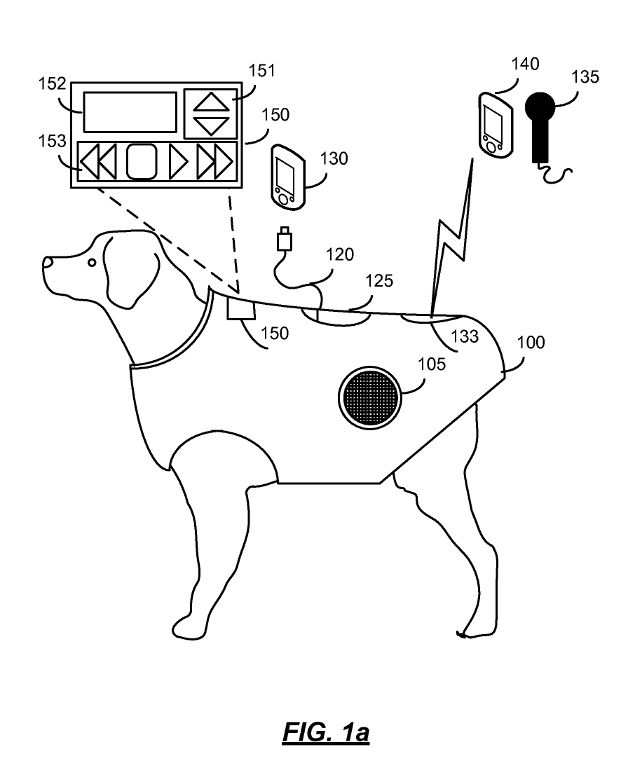

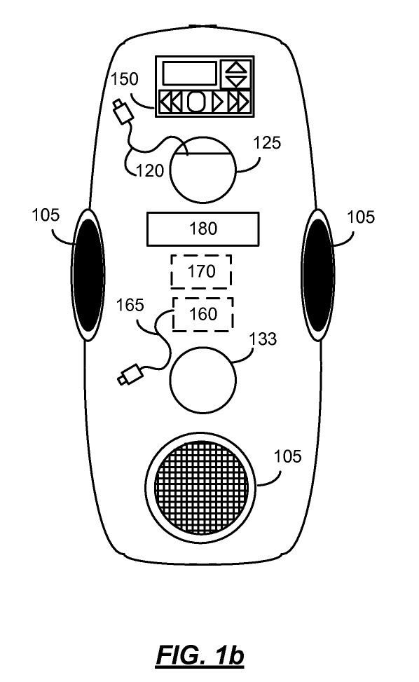

FIGS. 1a and 1b are perspective illustrations of an example garment 100 for an animal with integrated speakers. FIG. 1a is a side perspective illustration of the garment 100 and FIG. 1b is a top perspective illustration of the garment 100. While the garment 100 is shown as being worn by a dog, it is for illustrative purposes only. The garment 100 may be sized and worn by a variety of animals including dogs, cats, monkeys, goats, horses, elephants, sheep, cattle, etc. There is no limit to the size of type of animal that may wear the garment 100. Further, the garment 100 is not limited to the size and style shown in FIGS. 1a and 1b, any number of a variety of known animal clothing styles, types, and sizes may be used for the garment 100. Moreover, the various components of the garment 100 shown in FIGS. 1a and 1b are not shown to scale with respect to eat other or the garment 100, nor are the components limited to the illustrated locations of the garment 100.

The garment 100 may include a pair of speakers 105. Each speaker 105 may be selected so as to be large enough to provide sufficient sound clarity and volume, while minimizing the weight and size of the speaker 105 so as to not cause discomfort for the animal wearing the garment 100. Each speaker 105 may also be generally waterproof or water-resistant. In some implementations, the speakers 105 may be approximately 4 inches in diameter and have an impedance of approximately 16 ohm. Other impedance level speakers may also be used.

In some implementations, the speakers 105 may be placed on either side of the garment 100. As illustrated, the speakers 105 are placed approximate to the rear legs of the animal wearing the garment 100. In this position output of the speakers 105 is less likely to cause discomfort to the animal than a position close to the ears. Other positions may also be used for the speakers 105 and may depend on the type of animal and application used for the garment 100. For example, if the garment 100 is intended to be used as an amplifier or public address system, the speakers 105 may be placed farther away from the ears of the animal so that the animal is not bothered by the output of the speakers 105.

In some implementations, the speakers 105 are desirably placed and oriented on the garment 100 so as to allow bystanders or other individuals to hear the output of the speakers 105 while minimizing or preventing the animal wearing the garment 100 from hearing the output. For example, the speakers may be angled such that the sound is emitted towards the rear of the animal, and away from the ears of the animal. Any known methods or techniques for focusing music may be used. In some implementations, padding or insulation may be further placed behind or around the speakers 105 to minimize the vibrations felt by the animal and to otherwise reduce discomfort caused by the speakers 105.

In some implementations, the speakers 105 may include a dedicated woofer or subwoofer speaker. For example, as illustrated in FIG. 1b, an additional subwoofer speaker 105 is placed on the top of the garment 100. The subwoofer speaker 105 may provide additional low end frequency response to the garment 100, and may make the garment 100 more suitable for playing music. While shown on the top of the garment 100 in FIG. 1b, the subwoofer speaker 105 may be placed is variety of positions in the garment 100. Moreover, where a subwoofer speaker 105 is used, the garment 100 may include a crossover (not shown) to direct low frequencies to the subwoofer speaker 105, while the remaining high frequencies are directed to the other speakers 105, for example.

The garment 100 may further include an interface 120. The interface 120 may be adapted to connect to one or more sources 130 and may allow the output of the one or more sources 130 drive the output of the speakers 105. The sources 130 may be a variety of sources such as MP3 players, cell phones, and portable video game devices. Other sources 130 may include wired microphones and electronic or electric instruments, such as electric guitars and keyboards, for example. In some implementations, the interface 120 is an audio connector such as a 3.5 mm male audio connector. For example, the interface 120 may be inserted into the line out or headphone jack of a source 130 such as an MP3 player or cellular phone. In other implementations, the interface 120 is a connector used by computer devices such as USB (e.g., mini and micro USB) or fire wire. The interface 120 may also be a proprietary connector specific to a particular company or device. For example, the interface 120 may be an iPod™ type docking connector. Any type of connector known in the art may be used.

As described above, the interface 120 may be connected to a source 130. In some implementations, the garment 100 may include a pocket or pouch 125 that may conceal the interface 120 when not in use as well as hold and protect the source 130 when coupled to the interface 120. For example, where the source 130 is a portable MP3 player, the pouch 125 may receive the portable MP3 player into the garment 100. The pouch 125 may include a sealing means such as a snap or zipper to secure the source 130 into the pouch 125 as well as protect the source 130 and the interface 120. The pouch 125 may be large enough to receive a variety of source 130 types. However, other sized pouches 125 may be used. While only one pouch 125 and interface 120 are illustrated, the garment 100 may support multiple pouches 125 and interfaces 120 so that multiple types of sources 130 may be supported. In addition, while the pouch 125 and interface 120 are illustrated as located on the top of the garment 100, the pouch 125 and interface 120 may be located at a variety of positions and locations both inside and outside of the garment 100.

The garment 100 may further include an amplifier 170. The amplifier 170 may receive an audio signal from the interface 120, amplify the received signal, and provide the amplified signal to the speakers 105. The amplifier 170, interface 120, and speakers 105 may be connected using a series of wires (not shown) placed inside the garment 100. The wires may be placed between layers of fabric of the garment 100. The amplifier 170 may be a light weight, high efficient amplifier that is suitable to drive the speaker 105 at a suitable volume while using a minimum amount of power and producing a low level of heat. In some implementations, rather than have a separate amplifier 170 component, an amplifier 170 that is integrated into the source 130 may be used.

The garment 100 may further have a controller 150. In some implementations, the controller 150 may control the operations of the various components of the garment 100, including the source 130 when connected to the interface 120. For example, the source 130 may comprise an MP3 player such as the iPhone™ and may be connected to the garment 100 through an interface 120 such as an iPhone™ connector. When the iPhone™ is connected to the interface 120 and placed in the pocket 125, the operation of the iPhone™ may be controlled by a user through the controller 150. Any type of standalone controller or programmable device may be used to implement the controller 150. For example, the controller 150 may be implemented using a laptop, netbook, smart phone, cellular phone, or any other device.

In some implementations, the controller 150 may expose various controls to a user of the garment 100. As illustrated, the controller 150 includes volume controls 151, display screen 152, and play controls 153. The particular controls exposed to a user through the garment 100 may depend on the intended uses of the garment 100. For example, where the garment 100 is intended to operate as a public address system, only volume controls 151 may be exposed. In implementations where the user is expected to operate the garment 100 using a remote control or through the controls of the source 130, no controls may be exposed by the garment 100 and the controller 150 may either be not included in the garment 100 or may be hidden from the user inside the garment 100.

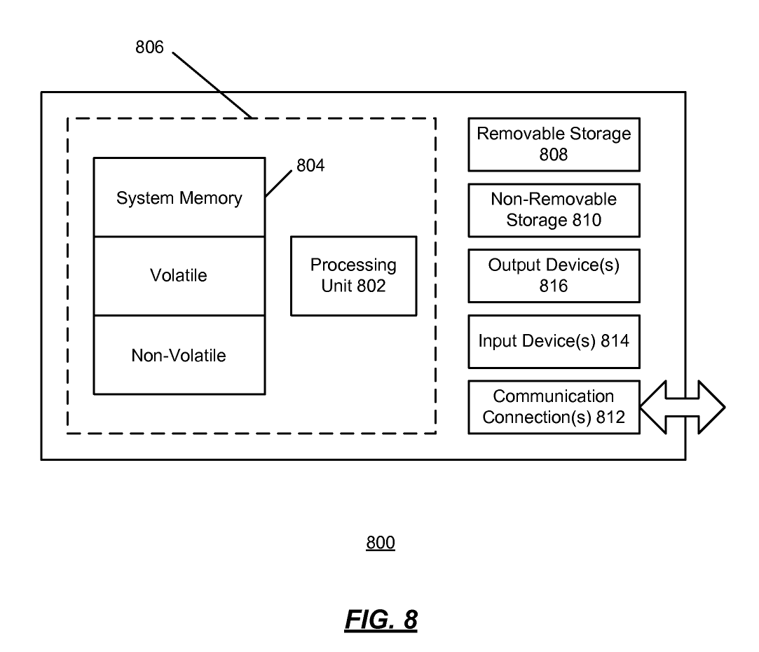

The controller 150 may be implemented by a variety of general purpose computers and computer devices. One such example is the computer device illustrated with respect to FIG. 8. Any combination of hardware and software known in the art may be used.

The garment 100 may further include a wireless receiver/transmitter 133. The wireless receiver/transmitter 133 may receive and transmit a variety of signals. In some implementations, the wireless receiver/transmitter 133 is a Bluetooth™ transmitter and receiver. Other receiver and transmitter types may also be used. For example, the wireless receiver/transmitter 133 may be a radio frequency signals, Wi-Fi signals (e.g., 802.11a/802.11b/802.11g/802.11n, etc.), infra red signals, wimax signals, cellular phone signals (e.g., CDMA, 3G, 2G, TDMA, etc.), and any other type of communication signal known in the art.

In some implementations, the wireless receiver/transmitter 133 may receive commands from a remote control device 140. The remote control device 140 may provide various controls signals that may be received by the wireless receiver/transmitter 133 and provided to the controller 150. The controller 150 may then control the operation of the source 130 (through the interface 120) according to the received commands. For example, a user may select a song to play on the source 130 using the remote 140. The controller 150 may receive the selection command via the wireless receiver/transmitter 133, and may generate a corresponding command suitable for the particular source 130. The source 130 may then receive the generated command through the interface 120 and begin playing the song selected by the user at the remote control device 140.

The remote control device 140 may be implemented using a variety of computer devices. For example, in one implementation, the remote control device 140 may be a simple hardware device that is sold and provided along with the garment 100. In other implementations, the remote control device 140 may be implemented as a software application that may be executed by a variety of computer devices such as cell phones, laptops, and other types of personal computers, for example.

In some implementations, the wireless receiver/transmitter 133 may receive signals from a wireless source 135. The wireless source 135 may include a variety of wireless sources such as cellular phones, wireless microphones, wireless instruments including keyboards and guitars, and wirelessly enabled MP3 players or other audio players. For example, an MP3 player may wirelessly stream music to the wireless receiver/transmitter 133. The wireless receiver/transmitter may receive the music stream and pass the music stream to the controller 150. The controller 150 may then process/decode the music stream into an audio signal, and pass the audio signal to the amplifier 170. The amplifier 170 may then output the audio signal through the speakers 105, for example.

In another example, the wireless source 135 may be a wireless microphone such as a Bluetooth™ headset. A user may speak into the microphone and a corresponding signal is generated by the wireless source 135 and received by the wireless receiver/transmitter 133. The wireless receiver/transmitter 133 may then provide the signal to the controller 150. The controller 150 may then process/decode the signal into an audio signal, and may pass the audio signal to the amplifier 170. The amplifier 170 may then output the audio stream through the speakers 105. In this way the garment 100 may be used as a public address system, for example.

The garment 100 may further include a power supply 160. The power supply 160 may include one or more batteries and may provide power to the various components of the garment 100. In some implementations, the batteries may be rechargeable batteries such as NiMH, NiCad, rechargeable alkaline, etc. Any type of rechargeable or non-rechargeable battery known in the art may be used. The number and capacity of the batteries that make up the power supply 160 may depend on a variety of factors such as the size of the animal that may be wearing the garment 100. For example, a garment 100 intended for a small dog may include fewer batteries than a garment 100 intended to be worn by an elephant.

The power supply 160 may be a separate component as illustrated in FIGS. 1a and 1b, or may be integrated into one or more of the other components of the garment 100. For example, the controller 150 and the amplifier 170 may each have their own power supply 160.

The power supply 160 may be recharged using recharge interface 165. In some implementations, the recharge interface 165 may be a standard power adapter that may be plugged into a 120V source found in most America homes. In other implementations, the recharge interface 165 may be a USB interface that may be used to receive power from any USB supporting device, such as a home computer. For example, a user may recharge the power supply 160 by connecting the recharge interface 165 to the USB interface of a home computer.

In some implementations, the garment 100 may further include one or more power generating components 180. For example, in one implementation, the power generating component 180 may be a solar panel or a series of solar panels. The solar panels may be arranged on the top of the garment 100 and or integrated into the fabric of the garment 100. The solar generating power component 180 may then provide power to the batteries of the power supply 160 and/or the various components of the garment 100 while the garment 100 receives sunlight. Other examples of the power generating component 180 may include a locomotion based power generating component 180 that uses the movement of the garment 100 to generate power. Thus, when the animal wearing the garment 100 moves, power may be generated by the power generating component 180.

### II. Example Component Configurations

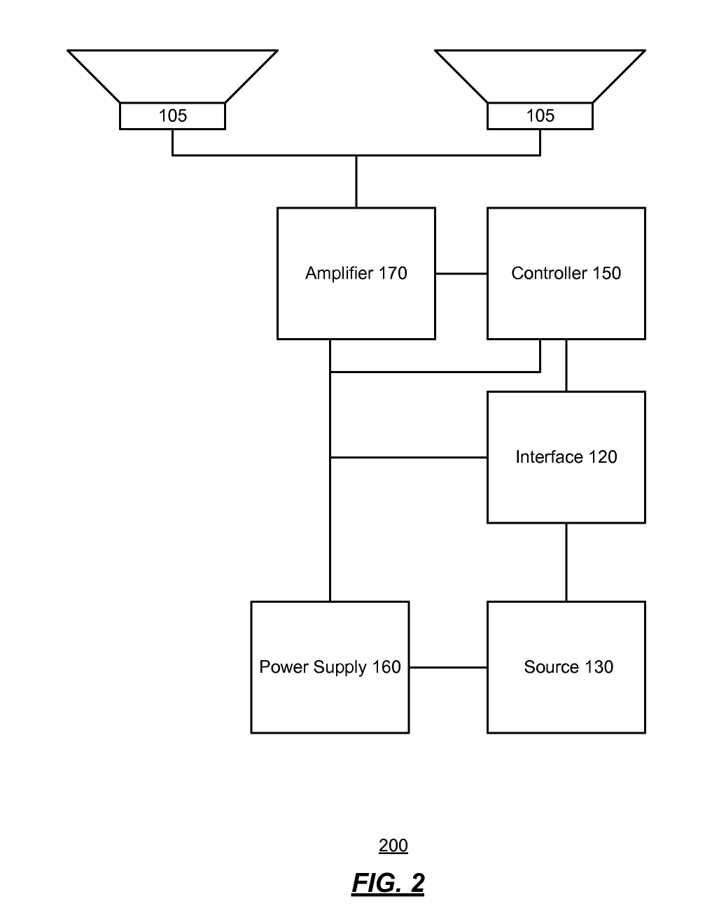

FIG. 2 is an illustration of the components 200 of an example garment for an animal. The illustrated components may be part of a garment for an animal such as the garment 100 illustrated in FIGS. 1a and 1b, for example. The components 200 are illustrated outside of the garment 100 so that the various connections between the components 200 may be illustrated. Note that the particular locations, sizes, and layout of the components 200 is for illustrative purposes only and not meant to limit the components 200 to the location, sizes, and layout shown.

As illustrated, the components 200 may include an interface 120. The interface 120 may be used to interface with a variety of sources. In the example shown the interface 120 is used to connect to a source 130. In some implementations, the source 130 is a preexisting source 130, that is the source 130 has been installed into the garment 100 and may be sold along with the garment 100, for example. The source 120 may be an MP3 player, or other audio source that has been “preloaded” with a variety of messages or novelty songs. For example, the messages may include phases such as “beware of dog” and the songs may include songs such as “Who let the dogs out.” In implementations where the garment 100 is likely to be used for police or rescue operations, the messages may be “Police” or “Help is on the way”. Any suitable messages or songs may be used.

In some implementations, the source 130 is provided by a user and may include a variety of devices including instruments, MP3 players, and wired microphones. The user may connect the interface 120 into the source 130. The interface 120 may include a variety of interface types suitable to connect to variety of sources 130. For example, the interface may include a USB connector or a 3.5 mm connector. Other interface types may also be used. For example, the source 130 may be an MP3 player such as the Zune™. A user may connect the Zune™ to the interface 120 to play songs stored on the Zune™ through the garment 100, for example.

The components 200 may further include a controller 150. The controller 150 may be a general purpose computing device such as the computing device illustrated in FIG. 8. The controller 150 may connect to the interface 120 and control the operation of the source 130 through the interface 120. In some implementations, the controller 150 may include an interface that is exposed to a user through the garment 100. In other implementations, the controller 150 may not have a visible interface, but is instead controlled by the user through a remote control, such as the remote control 140 illustrated in FIG. 1b, for example.

The components 200 may further include an amplifier 170. The amplifier 170 may receive a signal from one or all of the interface 120, source 130, or controller 150. The amplifier 170 may amplify the received signal and provide the amplified signal to the speakers 105. Any type of amplifier may be used for the amplifier 170. In some implementations, the amplifier 170 is a separate component. In other implementations, the amplifier 170 may be implemented into the other components 200 such as the source 130, controller 150, or the interface 120, for example.

The components 200 may further include a power supply 160. The power supply 160 may comprise one or more rechargeable batteries and may provide power to one or more of the components 200 including the source 130 interface 120, controller 150 and the amplifier 170. In some implementations, the power supply 160 is a separate component 200. In other implementations, each or some of the controller 150, interface 120, amplifier 170, and the source 130 may have their own integrated power supplies 160. Any type of power supply known in the art may be used.

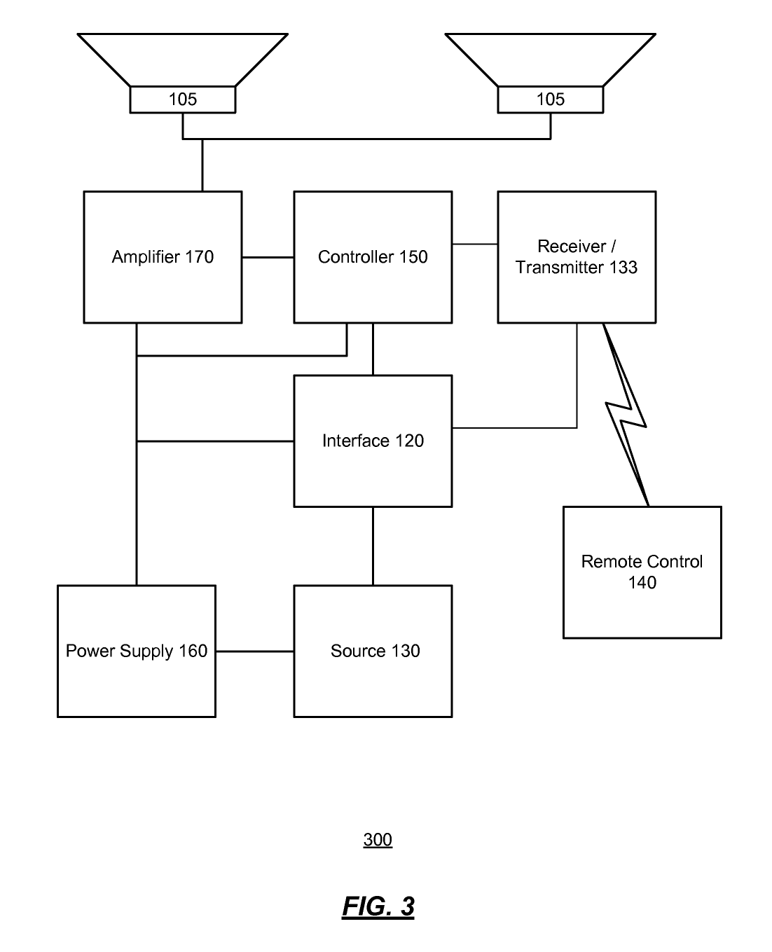

FIG. 3 is an illustration of the components 300 of an example garment for an animal. The illustrated components may be part of a garment for an animal such as the garment 100 illustrated in FIGS. 1a and 1b, for example. The components 300 are illustrated outside of the garment 100 so that the various connections between the components 300 may be illustrated. Note that the particular locations, sizes, and layout of the components 300 is for illustrative purposes only and not meant to limit the components 300 to the location, sizes, and layout shown.

As illustrated, the components 300 include the controller 150, amplifier 170, power supply 160, controller 150, source 130, interface 120, and speaker 105 of the components 200 illustrated in FIG. 2. In addition, the components 300 include a receiver/transmitter 133 and a remote control 140.

The receiver/transmitter 133 may be adapted to receive and transmit wireless signals in a variety of formats and protocols. These formats and protocols may include, for example, Bluetooth™, CDMA, Wi-Fi, RF, and wireless USB. Other formats and protocols may be used.

The receiver/transmitter 133 may receive wireless commands from a remote control 140. For example, the received commands may be commands to raise of lower the volume of the output of the speakers 105. The receiver/transmitter 133 may receive the commands and provide the commands to one or more of the components 300. In some implementations, the commands may be provided to the source 130 through the interface 120. In other implementations, the commands may be provided to the controller 150, which may then process the commands. Processing the commands may include generating new commands by the controller 150 and providing the generated commands to the source 130 via the interface 120, for example.

The remote control 140 may be implemented as a stand alone device. For example, the remote may be packaged along with the garment 100. In other implementations, the remote control 140 may be implemented as a software application or module that is configured to be executed on a variety of computing devices. For example, a user may download or otherwise install a remote control 140 application on a computing device such as an IPhone™. The user may then use the remote control 140 application executing on the iPhone™ to generate and transmit commands to the receiver/transmitter 133, for example. Any type of computing device may be used to implement the remote control 140 such as, for example, the computing device 800 illustrated with respect to FIG. 8.

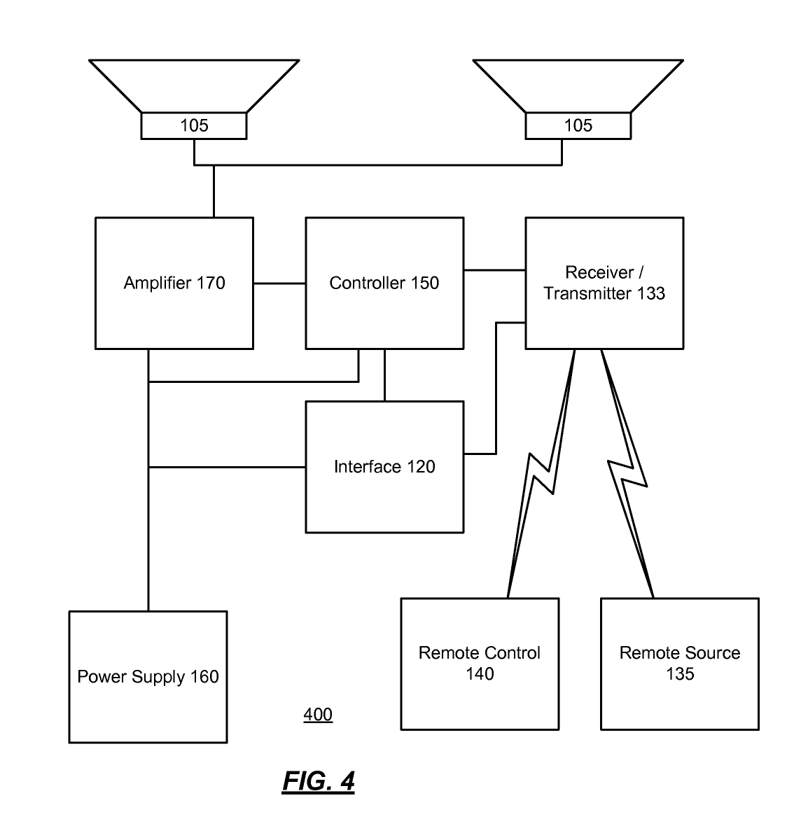

FIG. 4 is an illustration of the components 400 of an example garment for an animal. The illustrated components may be part of a garment for an animal such as the garment 100 illustrated in FIGS. 1a and 1b, for example. The components 400 are illustrated outside of the garment 100 so that the various connections between the components 400 may be illustrated. Note that the particular locations, sizes, and layout of the components 400 is for illustrative purposes only and not meant to limit the components 400 to the location, sizes, and layout shown.

As illustrated, the components 400 include the controller 150, amplifier 170, power supply 160, controller 150, interface 120, remote control 140, receiver/transmitter 133, remote control 140 and speaker 105 of the components 300 illustrated in FIG. 3. However, rather than the source 130, the components 400 include a remote source 135.

The remote source 135 may transmit a source signal (e.g., audio signal) to the receiver/transmitter 133. The receiver/transmitter 133 may provide the received signal to the amplifier 170 where it may be output through the speakers 105. In some implementations, the receiver/transmitter 133 may provide the signal to the controller 150, where it may be processed. The controller 150 may then provide the processed signal to the amplifier 170 where it may be output through the speakers 105.

The remote source 135 may be a variety of devices including musical devices and computer devices. For example, in one implementation, the remote source 135 may be an electric guitar with a wireless transmitter. In other implementations, the remote source 135 may be a wireless microphone. In other implementations, the remote source 135 is an MP3 player or other audio player. In some implementations, the remote source 135 may be implemented as a software application or module. The remote source 135 application may then be installed on a laptop, cell phone, or other computer device and may allow a user to stream audio signals from the computer device to the receiver/transmitter 133, for example.

While the remote control 140 and remote source 135 are illustrated as separate components, it is for illustrative purposes only. In some implementations, the remote control 140 and the remote source 135 may be implemented as part of the same software application or may be executed at the same computing device, for example.

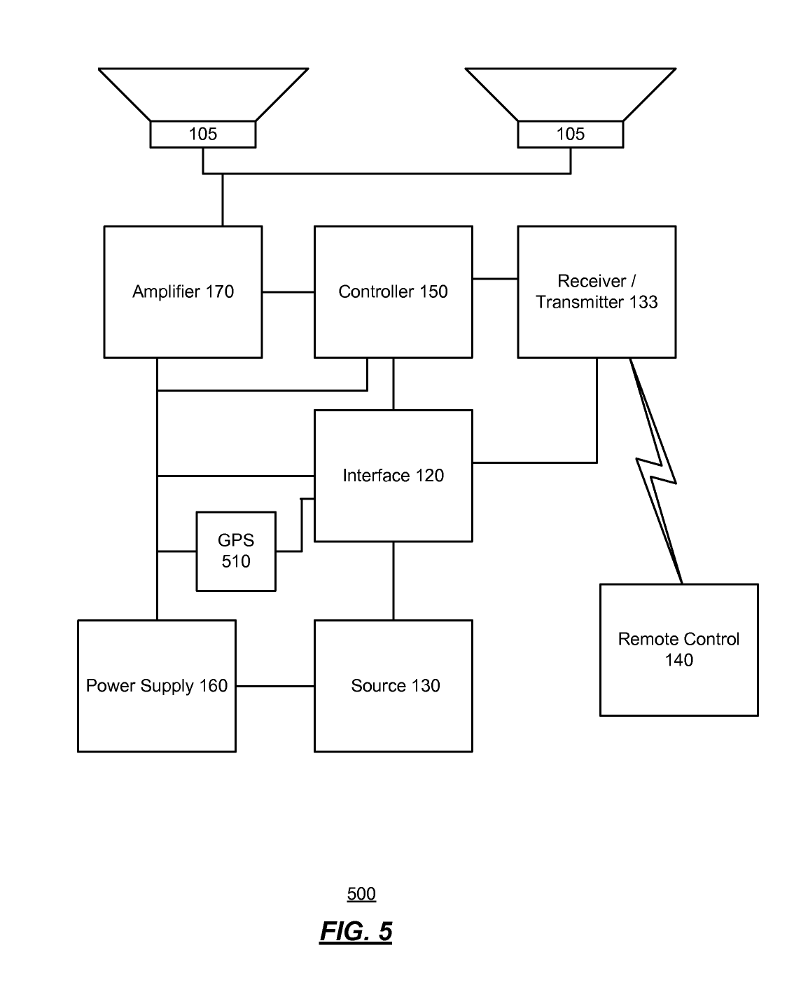

FIG. 5 is an illustration of the components 500 of an example garment for an animal. The illustrated components may be part of a garment for an animal such as the garment 100 illustrated in FIGS. 1a and 1b, for example. The components 500 are illustrated outside of the garment 100 so that the various connections between the components 500 may be illustrated. Note that the particular locations, sizes, and layout of the components 500 is for illustrative purposes only and not meant to limit the components 500 to the location, sizes, and layout shown.

As illustrated, the components 500 include the controller 150, amplifier 170, power supply 160, controller 150, source 130, interface 120, remote control 140, receiver/transmitter 133, and speakers 105 of the components 300 illustrated in FIG. 3. In addition, the components 500 further include a GPS 510.

In some implementations, the GPS 510 may connect to the controller 150 through the interface 120. The GPS 150 may be controlled by the controller 150 and provide location information to the controller 150. The controller 150 may then use the location information in a variety of applications. In some implementations, the controller 150 may display the location of the garment 100 to a user either through a display associated with the controller 150 on the garment 100, or through a display associated with the remote control 140.

In other implementations, the controller 150 (or alternatively, the remote control 140) may use the location information to recommend things nearby the current location. For example, the controller 150 may use a mapping application to determine dog parks or other pet friendly location near the current location of the animal wearing the garment 100.

In some implementations, the location information may be used to determine if a dog that is wearing the garment 100 has stepped outside a particular boundary. For example, a user may program the controller 150 (using either the controller 150, the remote control 140, or another computer device) with coordinates specifying a desired range for an animal that is wearing the garment 100. When the animal wearing the garment 100 exceeds the desired range as determined by the controller 150 using the GPS 510, the controller 150 may generate a sound through the speakers 105 to let the animal know that they have exceed the range, or the controller 150 may alert the owner of the animal through the remote control 140, for example. Other applications for the GPS 510 may be supported. For example, the controller 150 may determine the distance that an animal has walked using the GPS 510.

The GPS 510 may be integrated into the garment 100, or may be attached to the garment 100 by a user through either the interface 120 or the receiver/transmitter 133. The GPS 510 may be stored in the pouch 125, for example. The GPS 510 may be implemented using a variety of commercial GPS devices available. In some implementations, the GPS 510 may be provided by a standalone GPS such as those available from Garmin or TomTom. Alternatively, the GPS 510 may be a GPS integrated into a smart phone or other computer device, such as the iPhone™ of BlackBerry™ devices. For example, where a smart phone is serving as the source 130, controller 140, or the remote controller 150, a GPS 510 integrated into the smart phone may provide GPS location information.

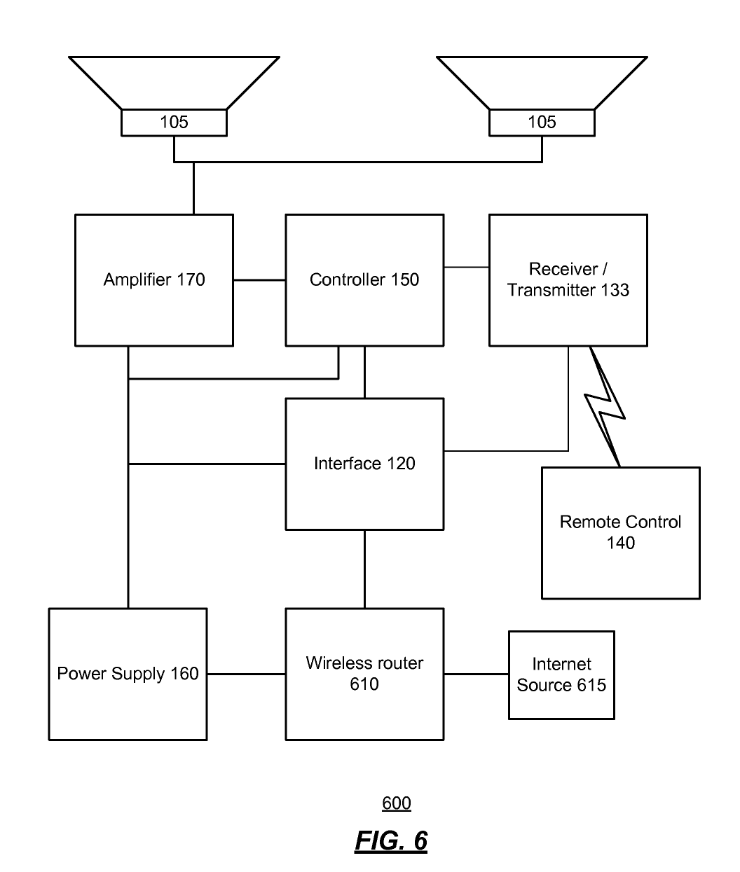

FIG. 6 is an illustration of the components 600 of an example garment for an animal. The illustrated components may be part of a garment for an animal such as the garment 100 illustrated in FIGS. 1a and 1b, for example. The components 600 are illustrated outside of the garment 100 so that the various connections between the components 600 may be illustrated. Note that the particular locations, sizes, and layout of the components 600 is for illustrative purposes only and not meant to limit the components 600 to the location, sizes, and layout shown.

As illustrated, the components 600 include the controller 150, amplifier 170, power supply 160, controller 150, interface 120, remote control 140, receiver/transmitter 133, and speakers 105 of the components 300 illustrated in FIG. 3. In addition, the components 600 include a wireless router 610 and an internet source 615.

The wireless router 610 may receive power from the power supply 160 and connect to the controller 150 via the interface 120. The wireless router 610 may connect to the internet source 615 and wirelessly share the internet source 615 among one or more users of wireless devices (not shown). The internet source 615 may be a variety of internet sources including, but not limited too, a cable or DSL model, an internet enabled cell phone or computer, and a 3G card or other internet provider access device.

For example, a user may connect or tether their Internet enabled cell phone (e.g., internet source 615) to the wireless router 610. The wireless router 610 may then share the internet source wirelessly (e.g., using 802.11a/b/g/n or other wireless protocol). Users with computers having the appropriate hardware, may wirelessly connect to the wireless router 610 and access the internet through the internet source 615. In this way, an animal wearing the garment 100 may be turned into a mobile internet access point.

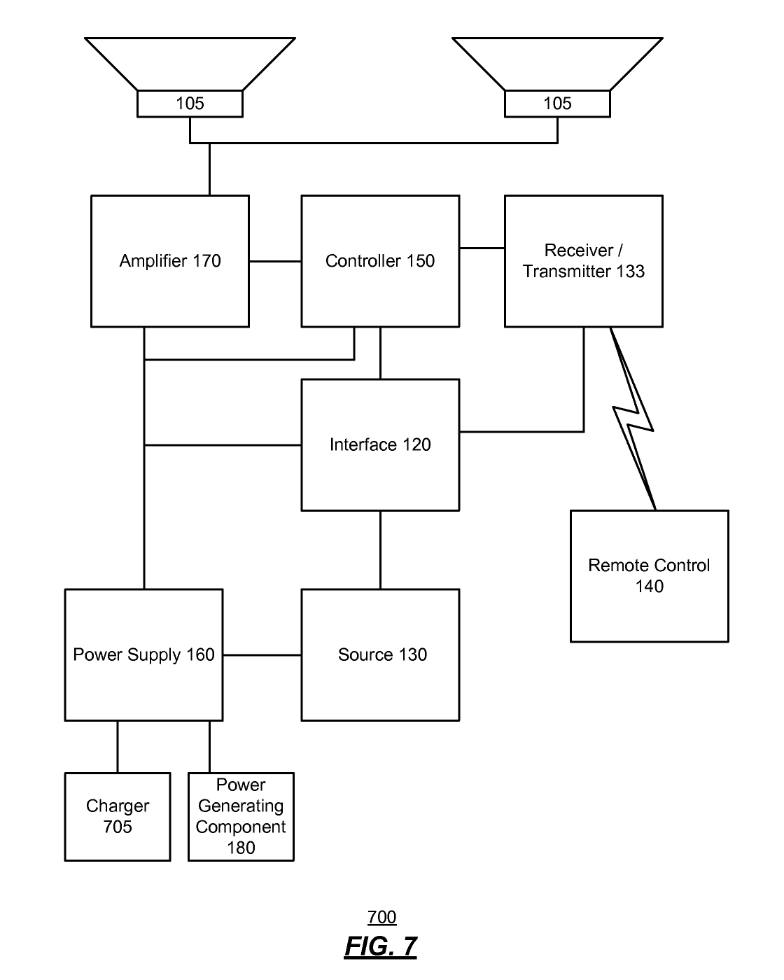

FIG. 7 is an illustration of the components 700 of an example garment for an animal. The illustrated components may be part of a garment for an animal such as the garment 100 illustrated in FIGS. 1a and 1b, for example. The components 700 are illustrated outside of the garment 100 so that the various connections between the components 700 may be illustrated. Note that the particular locations, sizes, and layout of the components 700 is for illustrative purposes only and not meant to limit the components 700 to the location, sizes, and layout shown.

As illustrated, the components 700 include the controller 150, amplifier 170, power supply 160, controller 150, source 130, interface 120, remote control 140, receiver/transmitter 133, and speaker 105 of the components 300 illustrated in FIG. 3. In addition, the components 700 include a charger 705 and a power generating component 180.

The power generating component 180 may generate power that may be used to charge the batteries of the power supply 160 and/or supply power to one or more of the components 700. In some implementations, the power generating component 180 may be a solar panel or array of solar panels. For example, the solar panels may be arranged on the surface of the garment 100. In some implementations, the power generating component 180 may be a locomotion based power generating component 180. For example, the locomotion power generation component 180 may be attached to the garment 100 and may generate power whenever the animal wearing the garment 100 moves using the motion and displacement caused by the moving animal. Other types of power generating components 180 may also be used.

The Charger 705 may be connected to the power supply 160 and may allow a plurality of devices to receive power from the power supply 160. For example, the charger 705 may allow users to connect their cell phones or other electronic devices and receive power from the power supply 160. The charger 705 may include multiple standard power outlet type connections as well as USB connections to allow multiple devices to be charged simultaneously. The combination of the power generating component 180 and the charger 705 may be useful to keep electronic device charged while in locations where conventional power sources may be unavailable. For example, camping hiking, etc.

### III. Example uses of the Garment 100

Portable Music Amplifier

In one implementation, the garment 100 may be used to turn a dog or other animal wearing the garment 100 into a portable stereo system. An owner of the dog wearing the garment 100 may connect an MP3 player, or other source 130, to the garment 100 through the interface 120. The output of the MP3 player may then be amplified by the amplifier 170 and played through the speakers 105 of the garment 100. The owner may then control the operation of the MP3 player using the remote control 140, for example. The owner may then walk their dog while enjoying the music stored on their MP3 player through the speakers 105.

Public Address System

In one implementation, the garment 100 may be used as a portable public address system. A user may connect a microphone to the garment 100. The microphone may be either connected using a wire (e.g., through the interface 120), or may be connected wirelessly (e.g., through the receiver/transmitter 133). Rather than using a separate megaphone or other type of public address system, the user may speak into the connected microphone and the user's voice may then be amplified and output by the speakers 105. Thus, the owner's dog is effectively turned into a portable public address system. As described previously, the speakers 105 are desirably placed in such a way on the garment 100 as to minimize the amount of noise/music that is received by the ears of the animal. For example, the speakers may be positioned so that the music is focused behind the animal and away from the ears of the animal.

The garment 100 may further be used as a portable amplifier for a variety of sources. For example, a user may connect an electric guitar or keyboard to the garment 100 and use their dog as a portable amplifier.

Police Dog

In one implementation, the garment 100 may be worn by a police dog and may be used to provide warnings or instructions regarding the police dog. For example, when the police dog is in pursuit of a suspect, the police office in control of the police dog may cause (e.g., using the remote control 140) a recording be played from the speakers 105 of the garment 100 that instructs the suspect to surrender and identifies the dog as a police dog. In another example where the police dog is looking for drugs or bombs, the speakers 105 may play a recording that explains that the dog is looking for drugs or bombs, and that the dog should not be touched or interfered with. As described above, the speakers 105 are oriented on the garment so as to not confuse the police dog or interfere with commands given by the officer. Thus, the speakers 105 may be oriented away from the ears of the animal wearing the garment.

Rescue Dog

In one implementation, the garment 100 may be worn by a dog involved in a search and rescue operation. For example, a dog that is looking for survivors of an earth quake may wear a garment 100 that is playing a message that identifies the dog as a rescue dog and that survivors should remain calm.

Mobile Communication Center

In one implementation, the garment 100 may be worn by a dog and used to provide internet or other communications. For example, in a remote location or at a disaster site, one or more dogs may be deployed each wearing a garment 100. The garments 100 may be outfitted with wireless routers 610 connected to an internet source 615, such as a cell phone, for example. Workers or other persons at the remote location or disaster site may receive internet access through the wireless routers 610 at each of the garments 100. Because the dogs wearing the garments 100 are mobile and have their own power sources 160, internet and other communication services may be provided where local power and internet communications are unavailable.

Portable Power Source

In one implementation, the garment 100 may be used to provide a portable power source. For example, a family may take their dog wearing a garment 100 on a camping trip. The family may use the charging station 705 of the power supply 160 to charge their cell phones or other electronic devices. The garment 100 may then recharge its power source 160 using a power generating component 180 such as one or more solar panels, for example.

Handicap Application

In one implementation, a seeing-eye dog may wear a garment 100. The garment 100 may play a recorded message through the speakers 105 that the owner is blind and to use caution. The message may be continuous or may be activated by the owner using the remote control 140, for example.

### IV. Computing Environment

FIG. 8 is a block diagram of an example computing environment that may be used in conjunction with example embodiments and aspects. The computing system environment is only one example of a suitable computing environment and is not intended to suggest any limitation as to the scope of use or functionality.

Numerous other general purpose or special purpose computing system environments or configurations may be used. Examples of well known computing systems, environments, and/or configurations that may be suitable for use include, but are not limited to, personal computers (PCs), server computers, handheld or laptop devices, multiprocessor systems, microprocessor-based systems, network PCs, minicomputers, mainframe computers, embedded systems, distributed computing environments that include any of the above systems or devices, and the like.

Computer-executable instructions, such as program modules, being executed by a computer may be used. Generally, program modules include routines, programs, objects, components, data structures, etc. that perform particular tasks or implement particular abstract data types. Distributed computing environments may be used where tasks are performed by remote processing devices that are linked through a communications network or other data transmission medium. In a distributed computing environment, program modules and other data may be located in both local and remote computer storage media including memory storage devices.

With reference to FIG. 8, an exemplary system for implementing aspects described herein includes a computing device, such as computing device 800. In its most basic configuration, computing device 800 typically includes at least one processing unit 802 and memory 804. Depending on the exact configuration and type of computing device, memory 804 may be volatile (such as random access memory (RAM)), non-volatile (such as read-only memory (ROM), flash memory, etc.), or some combination of the two. This most basic configuration is illustrated in FIG. 10 by dashed line 806.

Computing device 800 may have additional features/functionality. For example, computing device 800 may include additional storage (removable and/or non-removable) including, but not limited to, magnetic or optical disks or tape. Such additional storage is illustrated in FIG. 8 by removable storage 808 and non-removable storage 810.

Computing device 800 typically includes a variety of computer readable media. Computer readable media can be any available media that can be accessed by device 800 and include both volatile and non-volatile media, and removable and non-removable media.

Computer storage media include volatile and non-volatile, and removable and non-removable media implemented in any method or technology for storage of information such as computer readable instructions, data structures, program modules or other data. Memory 804, removable storage 808, and non-removable storage 810 are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the information and which can be accessed by computing device 1000. Any such computer storage media may be part of computing device 1000.

Computing device 800 may contain communications connection(s) 812 that allow the device to communicate with other devices. Computing device 800 may also have input device(s) 814 such as a keyboard, mouse, pen, voice input device, touch input device, etc. Output device(s) 816 such as a display, speakers, printer, etc. may also be included. All these devices are well known in the art and need not be discussed at length here.

Computing device 800 may be one of a plurality of computing devices 800 inter-connected by a network. As may be appreciated, the network may be any appropriate network, each computing device 800 may be connected thereto by way of communication connection(s) 812 in any appropriate manner, and each computing device 800 may communicate with one or more of the other computing devices 800 in the network in any appropriate manner. For example, the network may be a wired or wireless network within an organization or home or the like, and may include a direct or indirect coupling to an external network such as the Internet or the like.

It should be understood that the various techniques described herein may be implemented in connection with hardware or software or, where appropriate, with a combination of both. Thus, the processes and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an API, reusable controls, or the like. Such programs may be implemented in a high level procedural or object-oriented programming language to communicate with a computer system. However, the program(s) can be implemented in assembly or machine language. In any case, the language may be a compiled or interpreted language and it may be combined with hardware implementations.

Although exemplary implementations may refer to utilizing aspects of the presently disclosed subject matter in the context of one or more stand-alone computer systems, the subject matter is not so limited, but rather may be implemented in connection with any computing environment, such as a network or distributed computing environment. Still further, aspects of the presently disclosed subject matter may be implemented in or across a plurality of processing chips or devices, and storage may similarly be affected across a plurality of devices. Such devices might include PCs, network servers, and handheld devices, for example.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A garment for a dog comprising:
a pair of speakers comprising a left speaker and a right speaker, wherein the left speaker is placed in a left side of the garment between the front and rear legs of the dog and the right speaker is placed in a right side of the garment between the front and rear legs of the dog;
an audio source connected to the pair of speakers;
a wireless receiver adapted to receive signals from a remote control; and
a control processor adapted to control the audio source according to the received signals.

2. The garment of claim 1, wherein the speakers are further placed so that sound is output away from the ears of the dog.

3. The garment of claim 1, further comprising an amplifier connected to the audio source and the pair of speakers.

4. The garment of claim 1, further comprising a power source.

5. The garment of claim 4, wherein the power source is at least one rechargeable battery.

6. The garment of claim 4, wherein the power source is a solar panel attached to the garment.

7. The garment of claim 1, further comprising a wireless router and an internet source, wherein the wireless router is adapted to share the internet source among a plurality of computer devices.

8. The garment of claim 7, wherein the internet source is a cellular phone.

9. The garment of claim 1, wherein the remote control is a software application.

10. A garment for an animal comprising:
a pair of speakers;
an amplifier connected to the speakers through a plurality of wires located within the garment; and
an interface connected to the amplifier through the plurality of wires and adapted to connect to an external audio source.

11. The garment of claim 10, further comprising a control processor adapted to:
receive commands relating to the operation of the external source; and
control the external source through the interface.

12. The garment of claim 11, further comprising a wireless receiver adapted to receive commands relating to the operation of the external source from a remote control; and
provide the received commands to the control processor.

13. The garment of claim 10, wherein the interface is a wireless interface and the external audio source is a wireless external audio source.

14. The garment of claim 10, wherein the wireless audio source is a microphone.

15. The garment of claim 10, further comprising a power supply connected to the amplifier through the plurality of wires.

16. The garment of claim 15, wherein the power supply is a solar panel based power supply.

17. The garment of claim 10, further comprising at least one power outlet, wherein the power outlet is adapted to provide power from the power supply to a device connected to the power outlet.

18. The garment of claim 17 wherein the power outlet is a USB outlet.

19. The garment of claim 10, wherein the animal is one of a dog, a cat, a horse, or a monkey.

20. A garment for a dog comprising;
a wiring infrastructure located within the garment and adapted to carry power and data signals within the garment 100;
a speaker component adapted to reproduce an audio signal;
an amplifier component adapted to receive the audio signal through the wiring infrastructure, amplify the audio signal, and provide the audio signal to the speaker component through the wiring infrastructure;
an interface adapted to interface with an external audio source, receive the audio signal from the external audio source, and provide the audio signal to the amplifier component through the wiring infrastructure;
a control processing component adapted to receive instructions for the operation of the external audio source and provide the instructions to the interface though the wiring infrastructure; and
a remote control component adapted to wirelessly receive the instructions from a remote control device, and provide the instructions to the control processing component through the wireless infrastructure.
